(19) United States
(12) Patent Application Publication
(10) Pub. No.: US 2010/0051941 A1
(43) Pub. Date: Mar. 4, 2010

(54) DISPLAY DEVICE

(75) Inventor: Masahiro TANAKA, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/552,542

(22) Filed: Sep. 2, 2009

(30) Foreign Application Priority Data
Sep. 2, 2008 (JP) 2008-224303

(51) Int. Cl. H01L 33/00

(52) U.S. Cl. 257/43; 257/59; 257/E33.019

(57) ABSTRACT

A display device in which an OFF current of a thin film transistor formed of metal oxide semiconductor provided to the display device is further lowered thus ensuring the stability of an operation of the thin film transistor is provided. In a display device in which thin film transistors each of which has a semiconductor layer formed of a metal oxide semiconductor layer are mounted on a substrate, a silicon nitride film is arranged between the substrate and the thin film transistors as a barrier layer, and a gate insulation film of the thin film transistor is formed of a silicon nitride film formed by a plasma CVD method.

### CROSS-REFERENCE TO RELATED APPLICATIONS

The present application claims priority from Japanese Application JP 2008-224303 filed on Sep. 2, 2008, the content of which is hereby incorporated by reference into this application.

### BACKGROUND OF THE INVENTION

1. Field of the Invention

The present invention relates to a display device, and more particularly to a display device including thin film transistors each of which includes a metal oxide semiconductor.

2. Description of the Related Art

In a display device in which pixels are arranged on a substrate in a matrix array, each pixel is driven by an active matrix method.

That is, via each signal line (gate signal line) to which a plurality of pixels (a group of pixels) arranged in the row direction are connected, the group of pixels is sequentially selected. In this selection, pixel information is supplied to respective pixels of the group of pixels via a signal line (a drain signal line) used in common by a plurality of pixels arranged in the columnar direction. For this end, each pixel includes at least a thin film transistor which introduces information from the drain signal line to the pixel in response to a signal from the gate signal line.

There has been known a display device which mounts a drive circuit for supplying signals to the respective gate signal lines and the respective drain signal lines on the same substrate, and includes thin film transistors each of which is formed parallel to the thin film transistor of each pixel.

Although polycrystalline semiconductor made of poly-Si is often used for forming such a thin film transistor, recently, a thin film transistor formed of metal oxide semiconductor such as ZnO or InGaZnO4 has been attracting attentions.

This is because the thin film transistor formed of metal oxide semiconductor has characteristics of a small Vth shift and large mobility, can reduce the number of manufacturing steps, and can reduce a manufacturing cost relatively.

The thin film transistor formed of metal oxide semiconductor or the display device which includes such a thin film transistor are disclosed in JP-A-2006-186319 (patent document 1), JP-A-2006-165532 (patent document 2) or JP-A-2007-150157 (patent document 3), for example.

However, the thin film transistor formed of the metal oxide semiconductor mounted on the substrate of the display device is, in the same manner as the thin film transistor formed of the polycrystalline semiconductor made of poly-Si, for example, requested to satisfy a demand that an OFF current is lowered. This is because the lowering of an OFF current of the thin film transistor can enhance display quality of images in the display device.

Further, it is desirable that a substrate of a display device has a surface having small stepped portions. This is because when different kinds of signal lines are formed on a surface of the substrate in layers so that the number of stepped portions is increased, breakage or short-circuiting is liable to occur on the respective signal lines. In such a case, it is found that by forming a thin film transistor using metal oxide semiconductor, it is possible to decrease steps on the surface of the substrate by making use of peculiarity of the structure of such a thin film transistor.

### SUMMARY OF THE INVENTION

It is an object of the present invention to provide a display device in which an OFF current of a thin film transistor formed of metal oxide semiconductor provided to the display device is further lowered thus ensuring the stability of an operation of the thin film transistor.

It is another object of the present invention to provide a display device provided with thin film transistors formed of metal oxide semiconductor which can decrease the number of stepped portions on a surface of a substrate.

The present invention may have following constitutions, for example.

A first aspect of the invention is directed to, for example, a display device in which thin film transistors each having a semiconductor layer formed of a metal oxide semiconductor layer are mounted on a substrate, wherein a silicon nitride film is arranged between the substrate and the thin film transistors as a barrier layer, and a gate insulation film of the thin film transistor is formed of a silicon nitride film formed by a plasma CVD method.

According to a second aspect of the invention, in the display device of the first aspect, for example, the gate insulation film is formed by a plasma CVD method at a temperature of 300° C. or more.

According to a third aspect of the invention, in the display device of the first aspect, for example, the thin film transistor is configured such that a source electrode and a drain electrode are formed on an upper surface of the metal oxide semiconductor layer, and the metal oxide semiconductor layer, the source electrode and the drain electrode are formed by collective patterning after performing continuous sputtering.

According to a fourth aspect of the invention, in the display device of the first aspect, for example, a gate signal line which is connected to a gate electrode of the thin film transistor intersects with a drain signal line which is connected to a drain electrode of the thin film transistor by way of an insulation film, and the drain signal line is formed in an arcuate pattern as viewed in a plan view at a portion thereof which intersects with the gate signal line.

According to a fifth aspect of the invention, in the display device of the first aspect, for example, agate electrode of the thin film transistor is formed on the metal oxide semiconductor layer by way of the insulation film in an intersecting manner, and the metal oxide semiconductor layer is formed in an arcuate pattern as viewed in a plan view at a portion thereof which intersects with the gate electrode.

According to a sixth aspect of the invention, in the display device of the first aspect, for example, the thin film transistor has a source electrode and a drain electrode thereof formed on an upper surface of the metal oxide semiconductor layer, and the metal oxide semiconductor layer is formed on a periphery of the source electrode and the drain electrode in a state where the metal oxide semiconductor layer projects outwardly.

According to a seventh aspect of the invention, in the display device of the first aspect, for example, each of a source electrode of the thin film transistor, a drain electrode of the thin film transistor, a signal line which is connected to the source electrode, and a signal line which is connected to the drain electrode respectively has a round boundary between an upper surface thereof and a side wall surface thereof which intersects with the upper surface.

According to an eighth aspect of the invention, in the display device of the first aspect, for example, a thickness of a gate electrode of the thin film transistor and a thickness of a gate signal line which is connected to the gate electrode are set twice or more as large as a total thickness of a thickness of the metal oxide semiconductor layer and a thickness of a source electrode or a drain electrode.

According to a ninth aspect of the invention, in the display device having any one of the above-mentioned first to eighth aspects, for example, the display device is an organic EL display device.

The above-mentioned constitutions are described as merely one example, and various modifications are conceivable without departing from the technical concept of the present invention. Further, constitutional examples other than the above-mentioned constitutions become apparent from the description of the whole specification or drawings.

According to the display device having the above-mentioned constitutions, it is possible to further lower an OFF current of the thin film transistor formed of metal oxide semiconductor which is provided to the display device, and it is possible to ensure the stability of an operation of the thin film transistor.

Further, according to the display device having the above-mentioned constitutions, it is also possible to reduce the number of stepped portions formed on a surface of the substrate.

Other advantageous effects of the present invention will become apparent from the description of the whole specification.

### BRIEF DESCRIPTION OF THE DRAWING

FIG. 1 is a view showing a cross section of a thin-film-transistor forming portion of a display device of the present invention;

FIG. 2A and FIG. 2B are views showing the whole constitution of the display device of the present invention;

FIG. 3A is a view showing an equivalent circuit which is formed on a TFT substrate of the display device of the present invention and FIG. 3B is a view showing a timing chart of a signal;

FIG. 4A to FIG. 4H are step views showing a manufacturing method of the display device of the present invention while corresponding to the cross-sectional view shown in FIG. 1;

FIG. 5A to FIG. 5C are views showing a series of steps of manufacturing method of a pixel as viewed in a plan view;

FIG. 6A to FIG. 6C are views showing a series of steps of manufacturing method of a pixel as viewed in a plan view together with FIG. 5A to FIG. 5C;

FIG. 7 is a cross-sectional view showing the constitution of a channel portion of a thin film transistor of the display device of the present invention;

FIG. 8 is a cross-sectional view showing the constitution of an intersection portion of signal lines of the display device of the present invention;

FIG. 9 is a cross-sectional view showing the constitution of a contact hole of the display device of the present invention; and

FIG. 10 is a cross-sectional view showing the constitution of a terminal portion of the signal line according to the display device of the present invention.

### DESCRIPTION OF THE PREFERRED EMBODIMENTS

An embodiment of the present invention is explained in conjunction with drawings. Here, in the respective drawings, identical or similar constitutional elements are given same symbols and their repeated explanation is omitted.

### (Schematic Constitution of Display Device)

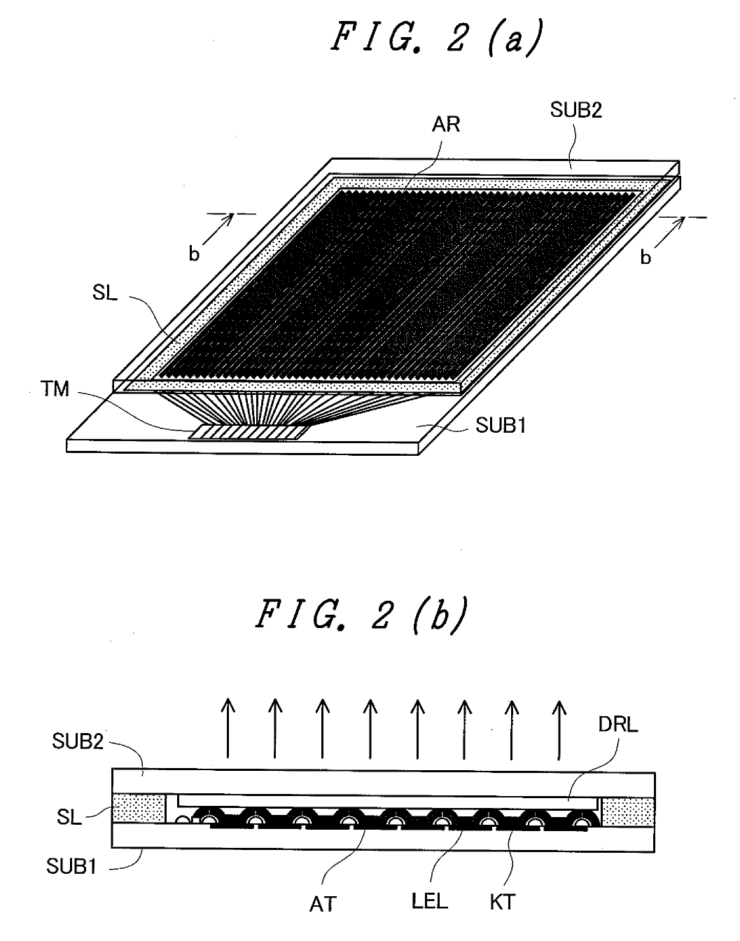

FIG. 2A is a perspective view of an organic EL display device of the present invention, for example, and FIG. 2B is a cross-sectional view taken along a line b-b in FIG. 2A.

In the organic EL display device shown in FIG. 2A, a TFT substrate SUB1 and a sealing substrate SUB2 which is arranged to face the TFT substrate SUB1 in an opposed manner constitute an envelope. The sealing substrate SUB2 is fixed to the TFT substrate SUB1 using a sealing member SL formed on a periphery of the sealing substrate SUB2 and made of an epoxy resin, for example. On a sealing-substrate-SUB2-side surface of the TFT substrate SUB1, a region which is defined by the sealing member SL constitutes a display region AR which is formed of a mass of pixels. Each pixel is constituted of thin film transistors, an electrode, a light emitting layer, signal lines and the like which are formed on the display region surface of the TFT substrate SUB1. The respective signal lines are pulled out to a region (a region disposed outside the sealing member SL) which is exposed to the outside from the sealing substrate SUB2 and the pulled-out portions of the signal lines form a terminal portion TM.

As shown in FIG. 2B, the pixel on the display region surface of the TFT substrate SUB1 includes a portion where a cathode electrode KT, a light emitting layer LEL and an anode electrode AT are sequentially stacked within a region surrounded by a pixel separation film. The light emitting layer LEL emits light when an electric current flows in the cathode electrode KT, the light emitting layer LEL and the anode electrode AT. The emitted light is radiated to the outside through the sealing substrate SUB2. A transparent desiccant layer DRL made of aluminum alkoxide which is high polymer alcohol, for example, is formed on a display region surface of the sealing substrate SUB2 in a state that a portion or the whole surface of the transparent desiccant layer DRL is in contact with the anode electrode AT. The transparent desiccant layer DRL is provided for preventing the deterioration of the properties of the light emitting layer caused by moisture.

### (Equivalent Circuit of Pixel)

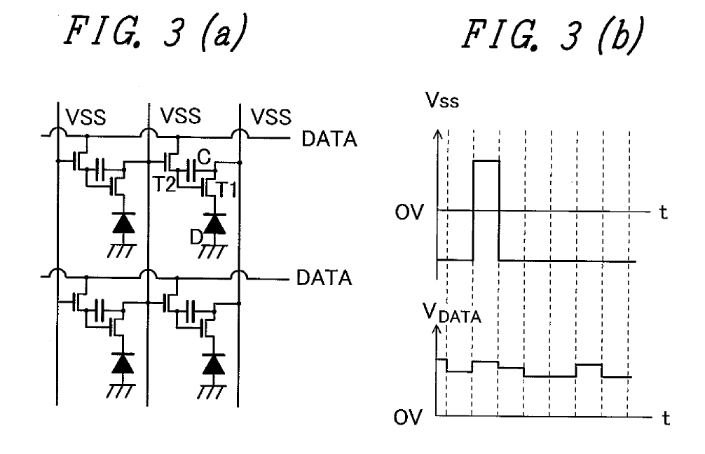

FIG. 3A shows one example of an equivalent circuit which is formed in the display region AR, and FIG. 3B is a timing chart of signals, wherein an upper part of FIG. 3B shows timing of a signal supplied to a Vss line and a lower part of FIG. 3B shows timing of a signal which is supplied to a Vdata line.

Although FIG. 3A is an equivalent circuit diagram, the drawing is depicted corresponding to the geometrical arrangement of pixels. In FIG. 3A, four (2×2) pixels are shown. In the drawing, a diode D which each pixel includes corresponds to the above-mentioned light emitting layer LEL. When an electric current flows in the light emitting layer LEL, the diode D emits light with a quantity of light corresponding to intensity of the electric current. The quantity of current is controlled by a transistor (thin film transistor) T1. An electric current which flows in the transistor T1 is decided based on a voltage applied to a gate electrode of the transistor T1, and the voltage corresponds to a voltage to be written in a capacitor C. That is, when a signal is supplied to the Vss line, a transistor (thin film transistor) T2 is turned on so that a voltage of a signal supplied to a Vdata line is written and held in the capacitor C.

### (Cross-Sectional Constitution of Pixel)

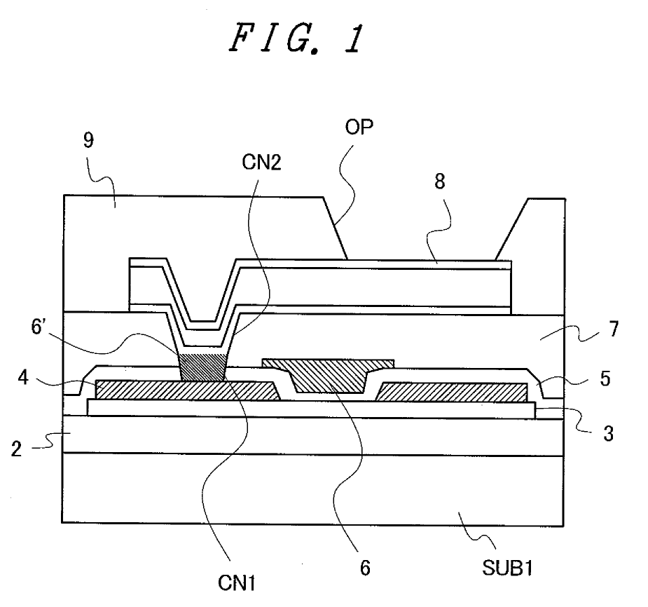

FIG. 1 is a cross-sectional view showing a portion of the pixel which is formed on a surface of the TFT substrate SUB1. In the pixel, out of a pair of electrodes which is formed so as to sandwich the transistor (thin film transistor) T1 and the light emitting layer LEL (not shown in the drawing) therebetween, one electrode (cathode electrode KT) 8 is shown. Accordingly, the capacitor C is not shown in FIG. 1.

In FIG. 1, a barrier layer 2 is formed on a surface (sealing-substrate-SUB2-side surface) of the TFT substrate SUB1. The barrier layer 2 is formed of a silicon nitride film. The barrier layer 2 functions as a layer for preventing the impurities present in the TFT substrate SUB1 from intruding into the inside of a semiconductor layer of the thin film transistor T1 described later. Here, the thin film transistor T1 is formed using a metal oxide semiconductor layer 3 and hence, it is confirmed that by forming the barrier layer 2 using a silicon nitride film rather than a silicon oxide film, for example, the above-mentioned function can be enhanced. The island-shaped gy metal oxide semiconductor layer 3 is formed on a surface of the barrier layer 2. The metal oxide semiconductor layer 3 is made of InGaZnOx, for example. A source/drain electrode 4 is formed on both ends of an upper surface of the metal oxide semiconductor layer 3 except for a center portion of the upper surface. An insulation film 5 is formed on the surface of the TFT substrate SUB1 in a state that the insulation film 5 covers the source/drain electrodes 4. The insulation film 5 functions as a gate insulation film in regions where the thin film transistors T1 are formed. A gate electrode 6 is formed on an upper surface of the insulation film 5 in a state that the gate electrode 6 overlaps with the metal oxide semiconductor layer 3 at a center portion of the metal oxide semiconductor layer 3. Although not shown in the drawing, the gate electrode 6 has the stacked structure consisting of Mo/Al/Mo. The gate electrode 6 is formed such that a portion of the gate electrode 6 on a side of one of source/drain electrodes 4 overlaps with a gate-electrode-6-side portion of the one of source/drain electrodes 4, and a portion of the gate electrode 6 on a side of another of source/drain electrodes 4 overlaps with a gate-electrode-6-side portion of the another of source/drain electrodes 4. Such constitution is adopted for increasing an amount of an electric current which flows when the transistor T1 is in an ON state. Here, in a portion of the insulation film 5 which covers one electrode (for example, the left electrode in the drawing) out of the source/drain electrodes 4, a contact hole CN1 through which a portion of the electrode is exposed is formed in advance. An intermediate interposed layer 6′ which is made of the same material as the gate electrode 6 and is formed simultaneously with the formation of the gate electrode 6 is formed through the contact hole CN1. An interlayer insulation film 7 is formed on the surface of the TFT substrate SUB1 in a state that the interlayer insulation film 7 covers the gate electrodes 6, a contact holes CN2 is formed in a portion of the inter layer insulation film 7, and the intermediate interposed layer 6′ is exposed through the contact hole CN2. Due to the intermediate interposed layer 6′, a depth of the contact hole CN2 formed in the interlayer insulation film 7 can be decreased thus facilitating the formation of the contact hole CN2. On a surface of the interlayer insulation film 7, one electrode (cathode electrode KT) 8 out of the pair of electrodes arranged with the light emitting layer LEL (not shown in the drawing) sandwiched therebetween is formed. The electrode 8 is electrically connected to one electrode out of the source/drain electrodes 4 of the transistor T1 via the contact hole CN2. The electrode 8 is constituted of an ITO/Ag/ITO stacked electrode, for example. An insulation film 9 made of a photosensitive polyimide resin or the like is formed on the surface of the TFT substrate SUB1. The insulation film 9 constitutes an element separation film by forming an opening portion OP at a center portion of the electrode 8 except for a periphery of the electrode 8.

Here, in FIG. 1, an electron transport layer, the light emitting layer, a hole transport layer, the anode electrode and the like are sequentially formed on an upper surface of the electrode 8 exposed through the insulation film 9 which functions as the element separation film. The detail of these parts including materials and the like of these parts is described later.

### (Manufacturing Method of Pixel)

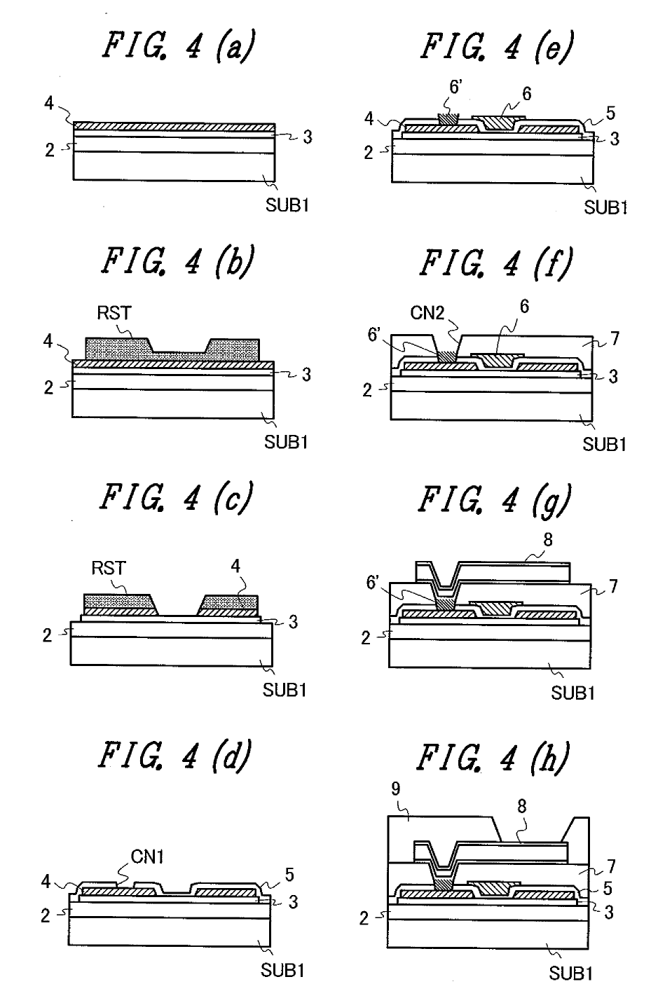

FIG. 4A to FIG. 4H are views showing steps of one example of a manufacturing method of the pixels shown in FIG. 1. The respective views showing steps are depicted corresponding to FIG. 1. Hereinafter, the method of manufacturing the pixel is explained in order.

### Step 1. (FIG. 4A)

First of all, a silicon nitride film is formed on the surface of the substrate SUB1 by a CVD method, and the silicon nitride film constitutes the barrier layer 2. Subsequently, the metal oxide semiconductor layer 3 made of InGaZnOx, for example, and the metal film 4 made of Mo, for example, are sequentially and continuously formed by a sputtering method. A film thickness of the barrier layer 2 is set to approximately 100 nm, a film thickness of the metal oxide semiconductor layer 3 is set to approximately 60 nm, and a film thickness of the metal film 4 is set to approximately 180 nm.

### Step 2. (FIG. 4B)

A photoresist is applied to a surface of the metal film 4 by coating, and a photoresist film RST consisting of a pattern (SD pattern) for forming respective electrodes of the thin film transistor T1 and a pattern for forming a channel portion of the thin film transistor T1 is formed by a photography technique. Here, the photoresist film RST is formed by the well-known so-called half exposure or the like, wherein the channel portion has a small thickness (0.4 μm) and the SD portion has a large thickness (1.4 μm).

Here, the above-mentioned “SD pattern” includes a pattern for forming a line layer which is integrally connected to the source electrodes and a pattern for forming a line layer which is integrally connected to the drain electrodes.

### Step 3. (FIG. 4C)

The metal film 4 which is exposed from the photoresist film RST and the metal oxide semiconductor layer 3 arranged below the exposed portion of the metal film 4 are etched by wet etching using the photoresist film RST as a mask. As an etchant used in such etching, a mixed acid of a phosphoric acid, an acetic acid and a nitric acid is used for etching the metal film 4, and an oxalic acid is used for etching the metal oxide semiconductor layer 3.

Thereafter, a surface of the photoresist film RST is removed by plasma ashing by a thickness of approximately 0.6 μm and hence, the photoresist film RST at the channel portion is removed thus exposing a surface of the metal film 4 in the channel portion. Then, by etching the metal film 4 which is exposed from the photoresist film RST using the remaining photoresist film RST as a mask, a surface of the metal oxide semiconductor layer 3 in the channel portion is exposed.

Through these steps, the SD line 4 (the patterned metal film 4 including the source/drain electrodes) can be formed without getting over the metal oxide semiconductor layer 3 thus avoiding the disconnection of the SD line 4 due to a stepped portion. Further, the SD line 4 is formed with an area smaller than an area of the metal oxide semiconductor layer 3 and hence, the insulation film 5 described later can more easily cover the stacked portion (the metal oxide semiconductor layer 3 and the SD line 4). Here, to allow the insulation film 5 to cover the stacked portion more easily, ashing is applied to the SD line 4 after peeling off the photoresist film RST so that corner portions of the SD line 4 are oxidized and, thereafter, the corner portions of the SD line 4 are washed with water thus rounding the corner portions.

### Step 4. (FIG. 4D)

The insulation film 5 is formed on the substrate SUB1 such that the insulation film 5 covers the SD lines 4 and the metal oxide semiconductor layers 3. The insulation film 5 functions as a gate insulation film of the thin film transistor T1. Thereafter, the contact hole CN1 is formed in the insulation film 5 using a photolithography technique so as to expose a portion of the electrode (for example, the source electrode)

Here, the insulation film 5 is an SiN film formed by decomposing SiH4 and NH3 using a plasma CVD method, and the insulation film 5 is etched by dry etching using an SF6 gas. A thickness of the insulation film 5 is set to approximately 150 nm.

A defect level at a deep portion in the SiN film which is formed by the plasma CVD method exhibits large film-forming temperature dependency. Although there is no problem in practical use when the film-forming temperature is not less than 300° C., a threshold voltage of the transistor is largely changed by the influence of a charge which is accumulated on the defect level when the temperature of the film-forming temperature is less than 300° C. Accordingly, when the SiN film which is formed by the plasma CVD method is used as the gate insulation film of the oxide semiconductor, a surface of the oxide semiconductor is partially nitrided so that nitride traps excessive electrons and hence, the carrier density is lowered thus giving rise to an advantageous effect that an OFF current of the transistor is lowered. Free electrons are liable to be generated in the oxide semiconductor due to the oxygen deficiency and hence, there exists a tendency that an OFF current of the transistor cannot be lowered largely. However, nitride traps the free electrons so that the OFF current can be suppressed.

### Step 5. (FIG. 4E)

The gate electrode 6 and the intermediate interposed layer 6′ are formed. Although not shown in the drawing, each of the gate electrode 6 and the intermediate interposed layer 6′ is formed of a stacked body having the three-layered structure consisting of an Mo layer, an Al layer and an Mo layer. Here, both the gate electrode 6 and the intermediate interposed layer 6′ have a thickness of approximately 500 nm, wherein a thickness of the Mo layer which constitutes a lower layer is set to approximately 50 nm, a thickness of the Al layer is set to approximately 400 nm, and a thickness of the Mo layer which constitutes an upper layer is set to approximately 50 nm. These thicknesses are determined so as to prevent the occurrence of disconnection of lines caused by the stepped portion. The stepped portion of the insulation film 5 which constitutes a background layer has a height of 240 nm. Accordingly, by setting the thicknesses of the gate electrode 6 and the intermediate interposed layer 6′ almost twice as large as the height of the stepped portion, it is possible to prevent the disconnection of the lines. For example, it is confirmed that by setting a film thickness of the metal oxide semiconductor layer 3 to 40 nm and a film thickness of the SD line 4 to 120 nm, the lines are hardly disconnected even when the thickness of the gate electrode 6 and the thickness of the intermediate interposed layer 6′ are set to approximately 350 nm.

### Step 6. (FIG. 4F)

The interlayer insulation film 7 is formed on the substrate SUB1 by applying, for example, photosensitive polyimide to the substrate SUB1 by coating such that the interlayer insulation film 7 covers the gate electrode 6 and the intermediate interposed layer 6′. A thickness of the interlayer insulation film 7 is set to approximately 1.5 μm. Thereafter, the contact hole CN2 which exposes a portion of the intermediate interposed layer 6′ is formed using a photolithography technique. By adopting the interlayer insulation film 7 which is formed by coating, the surface of the interlayer insulation film 7 can be leveled thus largely decreasing the scattering of light attributed to surface irregularities.

### Step 7. (FIG. 4G)

The electrode 8 is formed on the surface of the interlayer insulation film 7 in a state that a portion of the electrode 8 is electrically connected to the intermediate interposed layer 6′ via the contact hole CN2. The electrode 8 is formed such that an ITO/Ag/ITO stacked film is continuously formed using a sputtering method and the stacked film is patterned using a photolithography technique. The ITO films are etched using an oxalic acid, and the Ag film is etched using a mixed acid of a phosphoric acid, an acetic acid and a nitric acid. A film thickness of the ITO film which constitutes a lower layer is set to approximately 50 nm, a film thickness of the Ag film is set to approximately 150 nm, and a film thickness of the ITO film which constitutes an upper layer is set to approximately 30 nm.

### Step 8. (FIG. 4H)

The pixel separation film 9 which exposes a portion of the electrode 8 is formed. The pixel separation film 9 is formed, for example, by applying photosensitive polyimide to the interlayer insulation film 7 by coating and by exposing a portion of the electrode 8 using a photolithography technique.

### (Manufacturing Method of Pixel as Viewed in a Plan View)

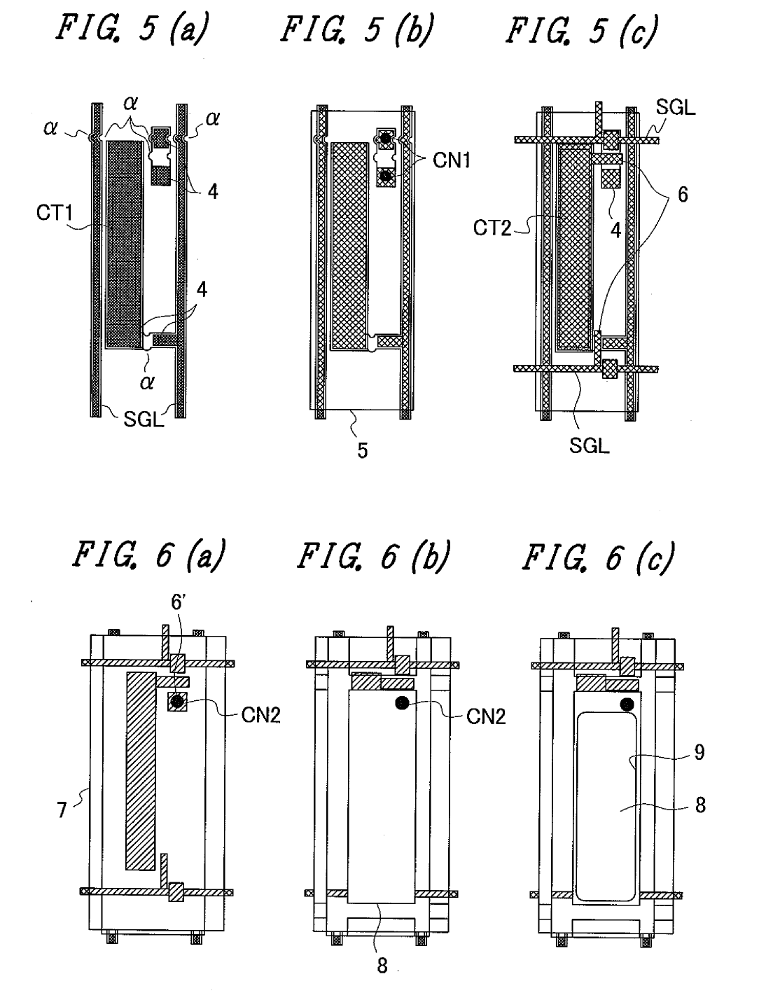

FIG. 5A to FIG. 5C and FIG. 6A to FIG. 6C are views showing the steps of the above-mentioned manufacturing method of the pixel as viewed in a plan view. In FIG. 5A to FIG. 5C and FIG. 6A to FIG. 6C, the capacitor C shown in FIG. 3A is also drawn.

First of all, FIG. 5A shows a planar surface of the pixel which corresponds to the step shown in FIG. 4C, wherein the metal oxide semiconductor layer 3, the source/drain electrodes 4, one electrode CT1 of the capacitor C, signal lines SGL and the like are shown. The source/drain electrodes 4, the one electrode CT1 of the capacitor C, the signal lines SGL and the like are respectively formed on an upper surface of the metal oxide semiconductor layer 3, and the metal oxide semiconductor layer 3 is formed so as to slightly project to the outside from the peripheries of the respective components. Due to such a constitution, there exists no possibility that the source/drain electrodes 4, the one electrode CT1 of the capacitor C, the signal lines SGL and the like respectively overhang from the metal oxide semiconductor layer 3 or project from the metal oxide semiconductor layer 3. Accordingly, it is possible to eliminate a possibility that the disconnection of lines is caused due to the stepped portion of the metal oxide semiconductor layer 3. As can be clearly understood from FIG. 5A, a portion of the metal oxide semiconductor layer 3 which intersects with the gate electrode (or gate signal line) is formed in an arcuate pattern (indicated by symbol a in the drawing,) as viewed in a plan view. Due to such a constitution, it is possible to obviate a phenomenon that an etchant impregnates between a photoresist and a material for forming the gate electrode 6 at a portion of the metal oxide semiconductor layer 3 where the gate electrode 6 gets over the metal oxide semiconductor layer 3 in forming the gate electrode 6 by etching thus causing the disconnection of lines.

FIG. 5B shows a planar surface of the pixel which corresponds to the step shown in FIG. 4D, and shows a state in which the insulation film 5 which functions as the gate insulation film is formed. In the insulation film 5, the contact holes CN1 which expose portions of the source/drain electrodes 4 of the transistor T1 respectively are formed.

FIG. 5C shows a planar surface of the pixel which corresponds to the step shown in FIG. 4E, wherein the gate electrode 6, the intermediate interposed layer 6′, other electrode CT2 of the capacitor C and the signal line SGL are shown. The capacitor C is constituted by overlapping the other electrode CT2 thereof on the one electrode CT1 thereof by way of the gate insulation film 5. Here, by arranging a periphery of the other electrode CT2 more inside than a periphery of the one electrode CT1, it is possible to obviate a possibility that the short-circuiting occurs due to a stepped portion formed on an outer peripheral portion of the other electrode CT2. As can be clearly understood from FIG. 5C, the contact holes CN1 which are formed in the insulation film 5 are configured such that the intermediate interposed layer 6′ which is formed at the time of forming the gate electrode 6 or the like using a material for forming the gate electrode 6 or the like is embedded in the contact holes CN1.

FIG. 6A shows a planar surface of the pixel which corresponds to the step shown in FIG. 4F, and shows a state in which the interlayer insulation film 7 is formed. In the interlayer insulation film 7, the contact hole CN2 which exposes the intermediate interposed layer 6′ connected to the one electrode out of the source/drain electrodes 4 of the transistor T1 is formed. In forming the contact hole CN2 in the interlayer insulation film 7, a depth of the contact hole CN2 can be decreased and hence, it is possible to obtain an advantageous effect that the contact hole CN2 can be easily formed.

FIG. 6B shows a planar surface of the pixel which corresponds to the step shown in FIG. 4G, and shows one electrode (cathode electrode KT) 8 out of the pair of electrodes which sandwiches the light emitting layer therebetween. The electrode 8 is electrically connected to the one electrode out of the source/drain electrodes 4 of the transistor T1 via the contact hole CN2.

FIG. 6C shows a planar surface of the pixel which corresponds to the step shown in FIG. 4H, and shows the insulation film 9 which functions as the pixel separation film. The insulation film 9 is formed on the substrate SUB1 in a state that the insulation film 9 covers a peripheral portion of the electrode 8 and a contact-hole-CN2 forming portion of the electrode 8.

### (Constitution of Channel Portion)

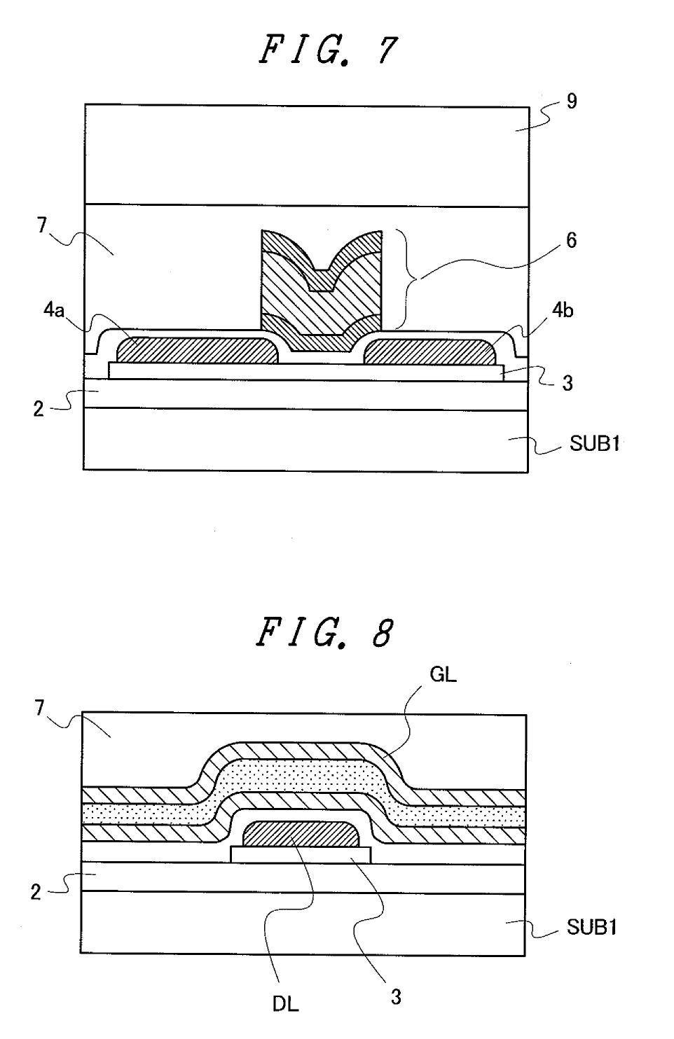

FIG. 7 is a cross-sectional view of the channel portion of the thin film transistor T1. As shown in FIG. 7, the gate electrode 6 is formed such that a source-electrode-4-side (indicated by symbol 4a in the drawing) portion of the gate electrode 6 overlaps with the source electrode 4a and a drain-electrode-4-side (indicated by symbol 4b in the drawing) portion of the gate electrode 6 overlaps with the drain electrode 4b. In the thin film transistor T1 which adopts the metal oxide semiconductor layer 3, the metal oxide semiconductor layer 3 is not doped with impurities and hence, the thin film transistor T1 has a characteristic of maintaining an OFF state when a gate voltage is not applied to the thin film transistor T1. Accordingly, to prevent an electric current from becoming hard to flow due to high resistance in an ON state, the gate electrode 6 has the above-mentioned constitution. However, such a constitution provides the structure where short-circuiting is liable to occur at the gate electrode 6 by breaking the gate insulation film 5 at the gate-electrode-6-side portion of the source electrode 4a or the gate-electrode-6-side portion of the drain electrode 4b. Accordingly, after forming the source electrode 4a and the drain electrode 4b, surfaces of the respective electrodes, particularly, corner portions of surfaces of the respective electrodes are oxidized by ashing and, thereafter, the oxidized portions are dissolved and removed by washing the respective electrodes with water so that the corner portions of the respective electrodes are rounded. That is, due to such a constitution, each of the source electrode 4a, the drain electrode 4b, and the respective signal lines which are connected to the source electrode 4a and the drain electrode 4b respectively has a boundary thereof defined between an upper surface thereof and a side wall surface thereof which intersects with the upper surface rounded.

### (Constitution of Intersecting Portion)

FIG. 8 is a cross-sectional view showing a portion of the gate signal line (signal line connected to the gate electrode 6: indicated by symbol GL in the drawing) which intersects with the drain signal line (indicated by symbol DL in the drawing) in a state that the gate signal line strides over the drain signal line. The drain signal line DL has a boundary thereof which is defined between an upper surface thereof and a side wall surface thereof which intersects with the upper surface rounded by ashing and washing with water. Due to such a constitution, the drain signal line DL can prevent the breaking of the gate insulation film 5. The drain signal line DL is formed on the metal oxide semiconductor layer 3 and has an area smaller than an area of the metal oxide semiconductor layer 3. Accordingly, a periphery of the metal oxide semiconductor layer 3 is configured to project outwardly from the drain signal line DL. Due to such a constitution, the metal oxide semiconductor layer 3 and the drain signal line DL form a stepped cross section so that the adhesion of the gate insulation film 5 which is formed over the metal oxide semiconductor layer 3 and the drain signal line DL is facilitated and hence, a height at which the gate signal line GL gets over the drain signal line DL at a time can be dispersed thus providing the constitution which makes the disconnection of the gate signal line GL difficult to occur.

### (Constitution of Contact Hole)

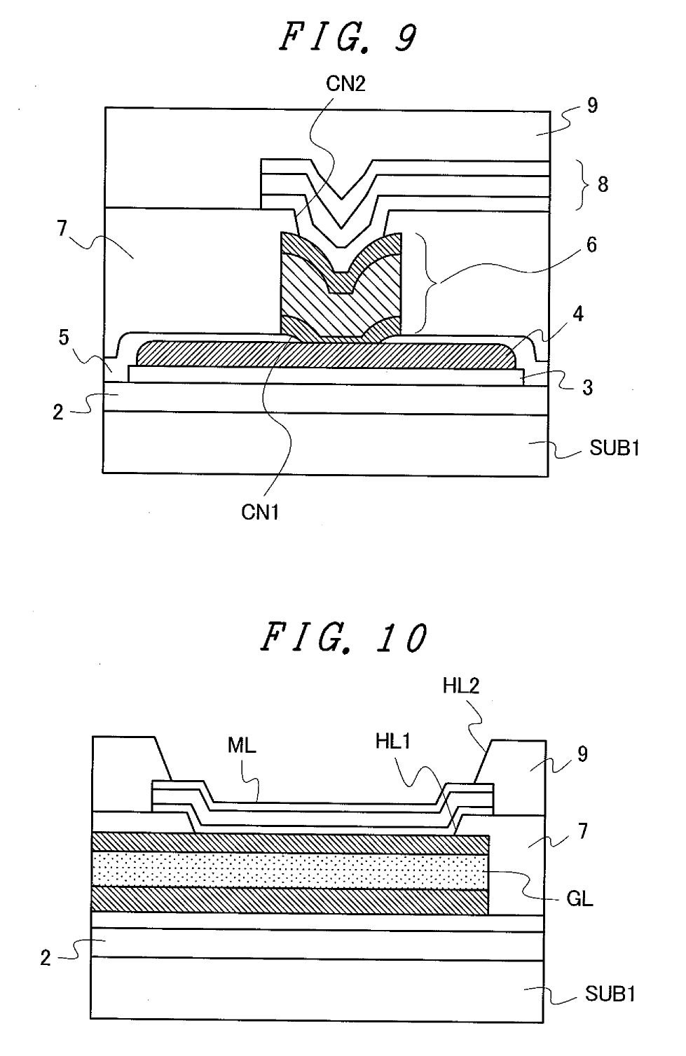

FIG. 9 is a cross-sectional view showing a contact hole for electrically connecting the source electrode 4a (or the drain electrode 4b) of the thin film transistor T1 and one electrode 8 out of the pair of electrodes which sandwiches the light emitting layer therebetween. The intermediate interposed layer 6′ is preliminarily formed on the source electrode 4a of the thin film transistor T1 through the contact hole CN1 which is formed in the gate insulation film 5. The intermediate interposed layer 6′ is formed simultaneously with the formation of the gate electrode 6 of the thin film transistor T1. Accordingly, in FIG. 9, the intermediate interposed layer 6′ is formed of a multi-layered metal-film stacked body in the same manner as the gate electrode 6. Accordingly, in forming the contact hole CN2 for exposing the intermediate interposed layer 6′ in the interlayer insulation film 7 which is formed so as to also cover the intermediate interposed layer 6′, a depth of the contact hole CN2 can be decreased and hence, the contact hole CN2 can be formed extremely easily.

### (Constitution of Terminal)

FIG. 10 is across-sectional view showing the constitution of a terminal of the gate signal line GL which is formed in regions other than the display region AR, for example.

In FIG. 10, the terminal portion (terminal forming portion) of the gate signal line GL is opened by an opening portion HL1 which is formed in the interlayer insulation film 7 formed over the gate signal line GL, and the terminal is formed of a terminal material layer ML which is formed so as to cover the opening portion HL1. The terminal material layer ML is formed of the same material as the electrode 8 and is formed simultaneously with the formation of the electrode 8. The terminal material layer ML is formed below the insulation film 9 which is formed of the same material as the element separation layer and is formed simultaneously with the formation of the element separation layer. A center portion of the terminal material layer ML is exposed through an opening portion HL2 formed in the insulation film 9.

### (Constitution of Light Emitting Portion)

In the constitution shown in FIG. 1, as described previously, on the upper surface of the cathode electrode 8 which is exposed from the insulation film 9 which constitutes the element separation film, the electron transport layer, the light emitting layer, the hole transport layer, the anode electrode and the like are sequentially formed.

To explain the above-mentioned constitution in more detail, for example, an electron injection layer is formed on the cathode electrode 8 by applying a first substance described later and a second substance described later which possess electron transportability to the cathode electrode 8 by co-vapor deposition, the electron transport layer 6 is formed on the electron injection layer by applying the above-mentioned first substance to the electron injection layer by vapor deposition and, further, the light emitting layer 5 is formed. Next, the hole transport layer is formed using a third substance described later, the hole injection layer is formed on the hole transport layer, and the anode electrode is formed by sputtering InZnO, for example.

The first substance is not particularly limited provided that the first substance exhibits the electron transportability and can be easily formed into a charge transfer complex due to co-vapor deposition with alkaline metal. As the first substance, for example, a metal complex such as tris (8-quinolinolate)aluminum, tris(4-methyl-8-quinolinolate)aluminum, bis(2-methyl-8-quinolinolate)-4-phenylphenolate-aluminum, bis[2-[2-hydroxyphenyl]benzooxasolate]zinc, 2-(4-biphenylyl)-5-(4-tert-butylphenyl)-1,3,4-oxadiazole, 1,3-bis[5-(p-tert-butylphenyl)-1,3,4-oxadiazole-2-yl]benzene or the like can be used.

The second substance is not particularly limited provided that the second substance is a material which exhibits the electron imparting property with respect to an electron transport substance. As the second substance, any substance having electron imparting property can be selected from, for example, alkaline metal such as lithium or cesium, alkaline earth metal such as magnesium or calcium, a metal group such as rare earth metal, and oxide, halide, carbonate or the like of the above-mentioned substances.

The third substance is a substance which exhibits the hole transportability. As the third substance, for example, a tetra-aryl benzine compound (triphenyldiamine: TPD), aromatic tertiary amine, a hydrazone derivative, a carbazole derivative, triazole derivative, an imidazole derivative, an oxadiazole derivative including an amino group, a polythiophene derivative, a copper phthalocyanine derivative or the like can be used.

The hole injection layer may be formed using an inorganic material such as MoO₃, WO₃ or V₂O₅. Accordingly, even when the anode electrode is formed by sputtering InZnO, it is possible to prevent the deterioration of an organic material.

A light emitting material used for forming the light emitting layer is not particularly limited provided that the light emitting material is produced by adding a dopant which emits fluorescence or white phosphorescence by the re-bonding of electrons and holes to a host material possessing the transportability of electrons and holes, and can be formed as a third layer by co-vapor deposition. The light emitting layer may be formed by using, as the host material, a complex such as tris(8-quinolinolate)aluminum, bis(8-quinolinolate)magnesium, bis(benzo(f)-8-quinolinolate)zinc, bis(2-methyl-8-quinolinolate)aluminum oxide, tris(8-quinolinolate)indium, tris(5-methyl-8-quinolinolate)aluminum, 8-quinolinolate lithium, tris(5-chrolo-8-quinolinolate)gallium, bis(5-chrolo-8-quinolinolate)calcium, 5,7-dichloro-8-quinolinolate aluminum, tris(5,7-dibromo-8-hydrixy quinolinolate)aluminum, poly[zinc(II)-bis-(8-hyroxy-5-quinolinile)methane], an anthracene derivative, a carbazole derivative or the like, for example.

Here, the dopant may be a substance which emits light by capturing electrons and holes and re-bonding the electrons and holes in a host material. For example, a pyrene derivative may be used for emitting red light, a coumarin derivative may be used for emitting green light, and a substance such as an anthracene derivative which emits fluorescence or a substance such as an iridium complex or a pyridinate derivative which emits phosphorescence may be used for emitting blue light.

The embodiment of the present invention has been explained heretofore by taking the organic EL display device as an example. However, the present invention is also applicable to other display devices such as a liquid crystal display device, for example.

What is claimed is:

1. A display device in which thin film transistors each of which has a semiconductor layer formed of a metal oxide semiconductor layer are mounted on a substrate, wherein
a silicon nitride film is arranged between the substrate and the thin film transistors as a barrier layer, and
a gate insulation film of the thin film transistor is formed of a silicon nitride film formed by a plasma CVD method.

2. A display device according to claim 1, wherein the gate insulation film is formed by a plasma CVD method at a temperature of 300° C. or more.

3. A display device according to claim 1, wherein the thin film transistor is configured such that a source electrode and a drain electrode are formed on an upper surface of the metal oxide semiconductor layer, and
the metal oxide semiconductor layer, the source electrode and the drain electrode are formed by collective patterning after performing continuous sputtering.

4. A display device according to claim 1, wherein a gate signal line which is connected to a gate electrode of the thin film transistor intersects with a drain signal line which is connected to a drain electrode of the thin film transistor by way of an insulation film, and
the drain signal line is formed in an arcuate pattern as viewed in a plan view at a portion thereof which intersects with the gate signal line.

5. A display device according to claim 1, wherein a gate electrode of the thin film transistor is formed on the metal oxide semiconductor layer by way of the insulation film in an intersecting manner, and
the metal oxide semiconductor layer is formed in an arcuate pattern as viewed in a plan view at a portion thereof which intersects with the gate electrode.

6. A display device according to claim 1, wherein the thin film transistor has a source electrode and a drain electrode thereof formed on an upper surface of the metal oxide semiconductor layer, and
the metal oxide semiconductor layer is formed on a periphery of the source electrode and the drain electrode in a state where the metal oxide semiconductor layer projects outwardly.

7. A display device according to claim 1, wherein each of a source electrode of the thin film transistor, a drain electrode of the thin film transistor, a signal line which is connected to the source electrode, and a signal line which is connected to the drain electrode respectively has a round boundary between an upper surface thereof and a side wall surface thereof which intersects with the upper surface.

8. A display device according to claim 1, wherein a thickness of a gate electrode of the thin film transistor and a thickness of a gate signal line which is connected to the gate electrode are set twice or more as large as a total thickness of a thickness of the metal oxide semiconductor layer and a thickness of a source electrode or a drain electrode.

9. A display device according to claim 1, wherein the display device is an organic EL display device.
